(19) United States
(12) Patent Application Publication
(10) Pub. No.: US 2022/0327259 A1
(43) Pub. Date: Oct. 13, 2022

(54) A METHOD FOR COMPUTER-IMPLEMENTED GENERATION OF A STATE MACHINE FROM A SIMULATED TECHNICAL COMPONENT IN A BLOCK-BASED SIMULATION MODEL

(71) Applicant: Siemens Aktiengesellschaft, München (DE)

(72) Inventor: Martin Witte, Schwabach (DE)

(21) Appl. No.: 17/641,479

(22) PCT Filed: Sep. 17, 2019
(86) PCT No.: PCT/EP2019/074868

§ 371 Date: Mar. 9, 2022

(51) Int. Cl. G06F 30/20; G06F 30/12

(52) U.S. Cl. CPC G06F 30/20; G06F 30/12

(57) ABSTRACT

A method for computer-implemented generation of a state machine from a simulated technical component in a block-based simulation model is disclosed, where the simulated technical component includes a plurality of variables, each variable having a value range with variable values which may be assigned to the respective variable. The method includes selecting one or more variables from the plurality of variables; generating, for each selected variable, a plurality of discrete states; generating an automaton for each selected variable; generating a first product automaton from the automatons of all selected variables; and removing superfluous vector transitions from the first product automaton based on predefined rules applying to the simulation model, where the first product automaton not containing the removed superfluous vector transitions is a second product automaton, which is the generated state machine.

The present patent document is a § 371 nationalization of PCT Application Serial No. PCT/EP2019/074868, filed Sep. 17, 2019, designating the United States, which is hereby incorporated by reference.

### TECHNICAL FIELD

The disclosure refers to a method and an apparatus for computer-implemented generation of a state machine from a simulated technical component in a block-based simulation model. Furthermore, the disclosure refers to a corresponding computer program product and a corresponding computer program.

### BACKGROUND

Block-based simulation models are known from the prior art. Those models enable simulations of a corresponding technical component being modelled by the simulation model. The technical component being simulated by the simulation model is described by a block within the simulation model where the block may be coupled to other blocks referring to other simulated technical components. In the following, the term technical component may refer to components of arbitrary size, wherein the component may also have sub-components. For example, a technical component may be a technical system including a plurality of sub-components.

H. Fu et al, “Hybrid automata of an integrated motor-transmission powertrain for automatic gear shift,” (2011 AMERICAN CONTROL CONFERENCE (ACC), 2011, pages 4604-4609, discloses a scheme of hybrid modelling of an integrated motor-transmission powertrain.

The behavior of technical components may also be described based on automatons, which are also referred as to state machines. Automatons for technical components represent the states of the technical components and transitions between those states. The description of a technical component by an automaton enables to apply specific analysis methods. Particularly, the behavior of a technical component described by an automaton may be formally verified. This is particularly useful in order to verify sequences of actions based on skills of the technical component described by the automaton.

Up to now, there do not exist any mechanisms enabling to convert a simulated technical component described by a simulation model into an automaton by the use of a computer.

### SUMMARY AND DESCRIPTION

Hence, it is an object of the disclosure to provide a computer-implemented method for generating a state machine (e.g., an automaton) from a simulated technical component in a block-based simulation model.

The scope of the present disclosure is defined solely by the appended claims and is not affected to any degree by the statements within this summary. The present embodiments may obviate one or more of the drawbacks or limitations in the related art.

The method enables a computer-implemented generation of a state machine from a simulated technical component in a block-based simulation model, where the simulated technical component is a block in the simulation model and includes a number of variables. Each variable has a value range with variable values which may be assigned to the respective variable when running a simulation of the technical component based on the simulation model. The variables may refer to continuous variables having a continuous variable range. Nevertheless, one or more of the variables may also refer to variables assuming discrete values. The simulated technical component may refer to any technical component, e.g., a component in an industrial automation system and/or an electric motor.

In the method, the following acts a) to e) are performed. In act a), one or more variables from the plurality of variables are selected. This may be performed automatically or semi-automatically as will be described later on.

In act b), a plurality of discrete states is generated for each selected variable, each state including a subset of values from the value range of the respective selected variable. In case that the selected variables have continuous value ranges, regions within the respective value ranges are defined which are associated with corresponding discrete states. In the same way, one or more discrete variable values may be associated with discrete states in case that the variable has discrete values. The discretization according to act b) is needed in order to generate automatons describing state changes as will be described in the following.

In act c), an automaton is generated for each selected variable, a respective automaton being represented by the states as generated in act b) of the respective selected variable and by one or more transitions from one state to another state of the respective variable. A respective transition is referenced by a label, and it is associated with a trigger condition defining the change of the respective selected variable resulting in the respective transition. In other words, the trigger condition defines that the respective transition is triggered when the value of the respective selected variable changes such that this change corresponds to a change between states as represented by the respective transition.

In act d), a first product automaton is generated from the automatons of all selected variables. This first product automaton includes a plurality of vector states representing all combination of states of all selected variables and a plurality of vector transitions for all transitions of single variables generated in act c). For example, each vector transition corresponds to a transition from one state to another state of a single variable as defined in act c) in a respective vector state where the states of the other variables in the respective vector state remain unchanged. In this first product automaton, the label and the trigger condition of the respective vector transition correspond to the label and trigger condition of the transition to which the respective vector transition corresponds.

In act e), superfluous vector transitions are removed from the first product automaton generated in act d). This removal is based on predefined rules applying to the simulation model. Particularly, those predefined rules describe the physics and/or the logic underlying the behavior of the simulated technical component. The removal of superfluous vector transitions results in a second product automaton which is the first product automaton not containing the removed superfluous vector transitions. This second product automaton is the state machine generated by the method. Due to the removal of superfluous vector transitions, the product automaton is reduced in size so that less computational recourses are needed when processing the product automaton.

The method enables a computer-implemented generation of an automaton based on a simulation model for a technical component. This is achieved by an adequate discretization of variables in the technical component and by creating a product automaton based on discrete states for the technical system. As a consequence, the simulated technical component may be subjected to methods which process automatons. For example, the automaton generated by the method may be used in implementations based on control theory.

In an embodiment, act a) is performed at least partly automatically based on a predefined selection of at least one variable. For example, the variables important for the behavior of the generated state machine are defined in advance. Alternatively, or additionally, act a) is performed at least partly semi-automatically in response to user inputs via a user interface, the user inputs specifying at least one variable which is to be selected.

In another embodiment, act b) is performed at least partly automatically based on predefined subsets of values from the value range of one or more selected variables. Alternatively, or additionally, act b) is performed at least partly semi-automatically in response to one or more user inputs via a user interface defining subsets of values from the value range of one or more selected variables.

Analogously to act a) and act b), act c) may also be performed at least partly automatically for at least one selected variable in order to generate an automaton for the at least one selected variable. For example, this automatic generation of an automaton may be performed in case that the respective variable has values with an order defining an adjacency relation. This is, e.g., the case when the variable refers to numbers. For variables having an order, transitions between adjacent regions of values corresponding to states may be defined up and down the ordering.

Additionally, or alternatively, act c) may also be performed at least partly semi-automatically in response to one or more user inputs via a user interface for at least one selected variable in order to generate an automaton for the at least one selected variable, the one or more user inputs specifying the transitions of the at least one selected variable. This semi-automatic generation of an automaton may be used for variables with non-ordered values.

In another embodiment, a validation act is automatically performed between act d) and act e), where the validation act tests whether the first product automaton generates outputs corresponding to outputs of the simulation model when running a simulation of the technical component based on the simulation model, where the method proceeds with act e) in case of a successful validation and where otherwise (e.g., in case of a failed validation) the method provides an input option on a user interface enabling one or more user inputs to modify the first product automaton, whereupon act d) is repeated based on the modified first product automaton.

Here and in the following, a successful validation refers to the scenario that the outputs of the simulation model correspond to the outputs of the product automaton whereas a failed validation refers to the scenario that at least one output of the simulation product does not correspond to the corresponding output of the product automaton. In the above validation act, the product automaton is the first product automaton. In the validation acts defined later on, the product automaton is a second product automaton or a third product automaton. The above validation act and also the validation acts described later on enable a test whether the product automaton corresponds to the simulated technical component in the simulation model. If not, means for modifying the automaton by a user are provided.

In another embodiment, a validation act is automatically performed after act e), where the validation act tests whether the second product automaton generates outputs corresponding to outputs of the simulation model when running a simulation of the technical component based on the simulation model, where the method either terminates or proceeds with another act without enabling a manual modification of the second product automaton in case of a successful validation. Otherwise, (e.g., in case of a failed validation), the method provides an input option on a user interface enabling one or more user inputs to modify the second product automaton, whereupon act e) is repeated based on the modified second product automaton.

In another embodiment, the second product automaton is further processed after act e) by act f) including one or more merging operations, where in a respective merging operation several vector states of the second product automaton differing in the value of a single variable are merged to a common vector state substituting the merged vector states, the vector transitions referring to the merged vector states being configured to vector transitions referring to the common vector state, thus resulting in a third product automaton. This act has the advantage that the size of the second product automaton is reduced.

Depending on the circumstances, at least one merging operation is performed automatically based on predefined rules and/or at least one merging operation is performed semi-automatically in response to one or more user inputs via user interface, the one or more user inputs specifying the vector states to be merged.

In an embodiment, the vector transitions of the merged vector states are configured to vector transitions referring to the common state as follows: i) in case that a vector transition refers to a vector transition from one merged vector state to another merged vector state, a self-loop transition is generated from the common vector state to the common vector state having a new label and the same trigger condition as the vector transition from the merged vector state to the other merged vector state; ii) in case that there are several vector transitions from a non-merged vector state to different merged vector states, a single vector transition having a new label is generated, the trigger condition being an OR concatenation of the trigger conditions of the several vector transitions; and iii) in case that there are several vector transitions from different merged vector states to different non-merged vector states being referenced by the same label and trigger condition, each vector transition of the several vector transitions receives a different label and a trigger condition discriminating between different merged vector states.

In another embodiment, a validation act is automatically performed after act f), where the validation act tests whether the third product automaton generates outputs corresponding to outputs of the simulation model when running a simulation of the technical component based on the simulation model, where the method terminates in case of a successful validation and where otherwise, (e.g., in case of a failed validation), the method provides an input option on a user interface enabling one or more user inputs to modify the third product automaton, whereupon act f) is repeated based on a modified second product automaton.

Besides the above method, the disclosure refers to an apparatus configured to perform the computer-implemented method or one or more embodiments of this method. In other words, the apparatus includes one or more processors configured to perform acts a) to e) and optionally perform acts of certain embodiments disclosed herein.

Furthermore, the disclosure refers to a computer program product with program code, which is stored on a non-transitory machine-readable carrier, for carrying out the method or one or more embodiments thereof when the program code is executed on a computer.

Moreover, the disclosure refers to a computer program with program code for carrying out the method or one or more embodiments thereof when the program code is executed on a computer.

### BRIEF DESCRIPTION OF THE DRAWINGS

In the following, embodiments of the disclosure are described in detail with respect to the accompanying drawings, wherein:

FIG. 1 depicts an example of a simulated technical component based on which a variant of the disclosure is described.

FIG. 2 is a flowchart illustrating the acts of an embodiment.

FIG. 3 is an illustration of the automatons generated in act S3 of FIG. 2.

FIG. 4 is an illustration of the first product automaton generated in act S4 of FIG. 2.

FIG. 5 is an illustration of the second product automaton generated in act S5 of FIG. 2.

FIG. 6 is an illustration of the third product automaton generated in act S6 of FIG. 2.

### DETAILED DESCRIPTION

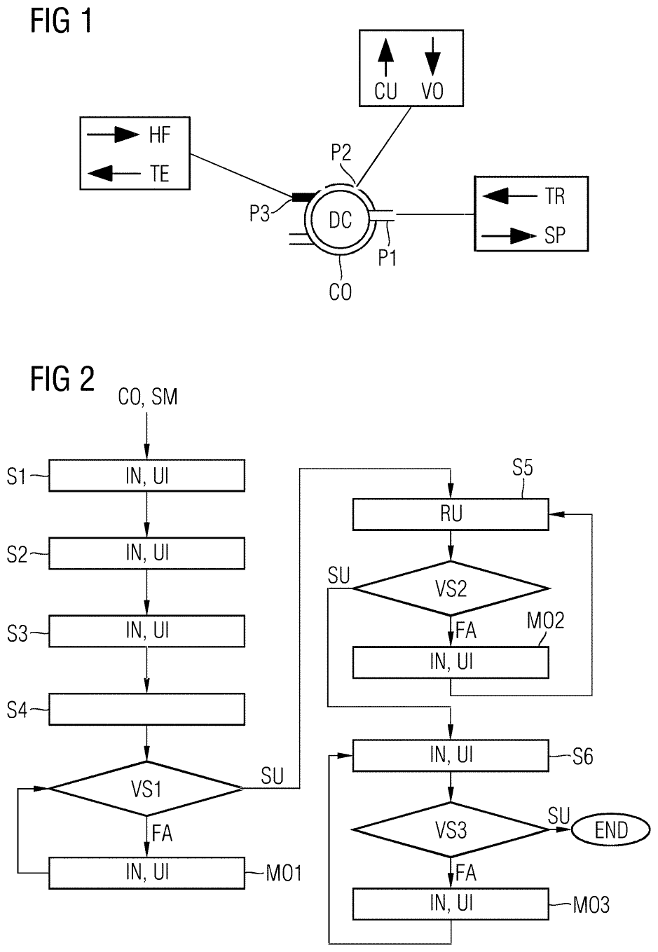

In the following, an embodiment of the disclosure is described with respect to the simulated technical component CO shown in FIG. 1. This component is an electric motor in a block-based simulation model and forms a corresponding block in this model. The block-based simulation model is the known Amesim model for DC motors. Nevertheless, another known simulation model for simulating such a motor or another technical component may be used for implementing the disclosure, e.g., the simulation models SysML or Simulink.

The operation of the motor in FIG. 1 during a simulation by the Amesim model is described by values of variables at respective ports P1, P2, and P3. Port P1 provides the variable speed SP and the variable torque TR. The speed refers to the rotation speed of the motor CO, whereas the torque refers to the torque provided by the motor. Port P2 provides the variable current CU and voltage VO referring to the electric current and voltage in the DC motor. Port P3 provides the heat flow rate HF and the temperature TE referring to the heat flow rate occurring in the motor and the temperature of the motor.

As indicated in FIG. 2, the simulation model SM simulating the motor CO is used as an input for the method as described in the following. The method of FIG. 2 converts the motor described by the simulation model SM in a state machine having the same behavior as the motor in the simulation model. This state machine (also designated as automaton) may thereafter be used for different purposes, e.g., for implementations in control theory or other fields where automatons may be used.

In act S1 of FIG. 2, some variables of the variables SP, TR, CU, VO, HF, and TC are selected. Those variables are relevant for aspects modelled in the state machine. The selection may be predefined. Additionally, or alternatively, some selected variables may be defined based on inputs IN on a user interface UI. In other words, the selection is based on user inputs IN processed in the method of the FIG. 1.

In the embodiment described herein, the three variables SP, TR, and VO are selected as the relevant variables. Each of the selected variables SP, TR, and VO is characterized by a continuous value range of values which may be assumed by the respective variable. However, in order to use those variables for state machines, discrete states of those variables need to be generated. This discretization is performed in act S2 of FIG. 1.

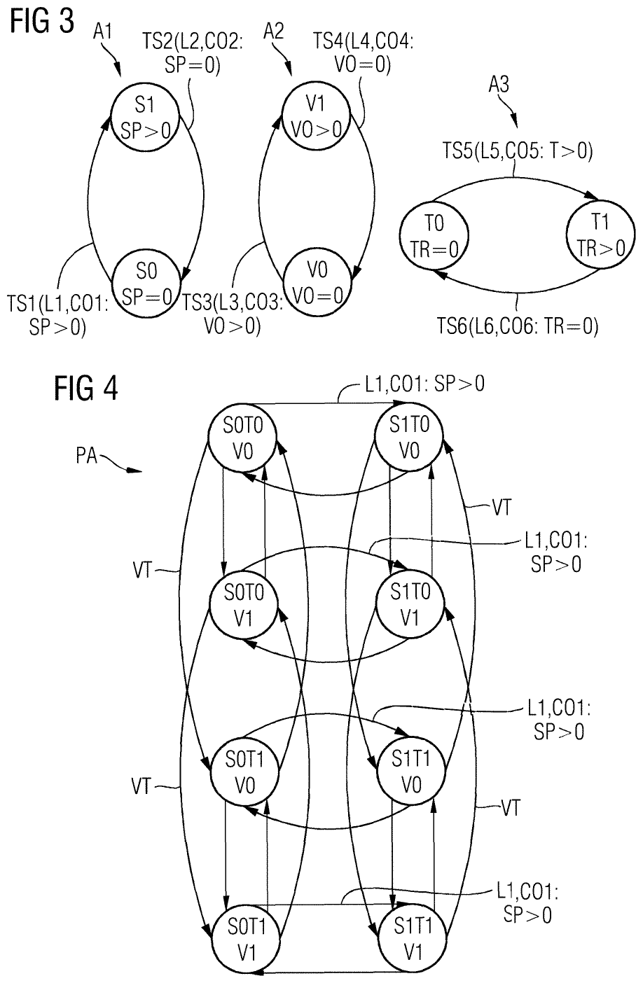

In act S2, each variable is divided in two regions, namely a region, where the variable has the value 0, and the region, where the variable has a value greater than 0. Each region forms a respective state. For the variable speed SP, a speed equal to 0 is indicated as state S0 (SP=0) whereas a state of a speed greater than 0 is indicated as state S1 (SP>0). For the variable torque TR, a state of zero torque is indicated as state T0 (TR=0) whereas a state of torque greater than 0 is indicated as state T1 (TR>0). For the variable voltage VO, a state with zero voltage is indicated as state V0 (VO=0) whereas a state with a voltage greater than 0 is indicated as state V1 (VO>0). The above states are shown in FIGS. 3 to 6 which will be described later on.

As a result of act S2, the above defined states S0, S1, V0, V1, T0, and T0 are provided for defining automatons in act S3, as will be described in the following. In act S3, an automaton A1 is generated for variable SP, an automation A2 for variable VO, and an automaton A3 for variable TR. Those automatons are shown in FIG. 3. Each automaton is characterized by the states which may be assumed by the respective variable as well as possible transitions between the states which are indicated as arrows in FIG. 3.

As seen from FIG. 3, there are six transitions TS1 to TS6. Each transition is specified by a label and a trigger condition defining the change of the respective variable resulting in the transition. According to FIG. 3, the variable SP of automaton A1 has the transition TS1 from state S0 to S1 associated with label L1 and trigger condition CO1 defined by SP>0. Furthermore, the variable SP has the transition TS2 from state S1 to S0 associated with label L2 and trigger condition CO2 defined by SP=0. The variable VO of automaton A2 has the transition TS3 referring to the change from state V0 to state V1 and being associated with label L3 and trigger condition CO3 defined by VO>0. Furthermore, variable VO has the transition TS4 referring to a change from state V1 to state V0 and being associated with label L4 and trigger condition CO4 defined by VO=0. Moreover, the variable TR of automaton A3 has the transition TS5 from state T0 to state T1 being associated with label L5 and trigger condition CO5 defined by T>0. Moreover, the variable TR has the transition TS6 from state T1 to state T0 being associated with label L6 and trigger condition CO6 defined by TR=0.

In the embodiment described herein, the automatons are generated automatically. This is because there are ordered sets of state variables based on adjacent value regions of variables. Therefore, transitions between adjacent regions may be defined as corresponding state transitions. However, in case that variables have non-ordered regions, act S3 may also be performed semi-automatically. In this case, a graphical representation of the regions is generated on a user interface UI. Based on this graphical representation, a user may define respective transitions between regions by user inputs IN, resulting in the generation of corresponding automatons.

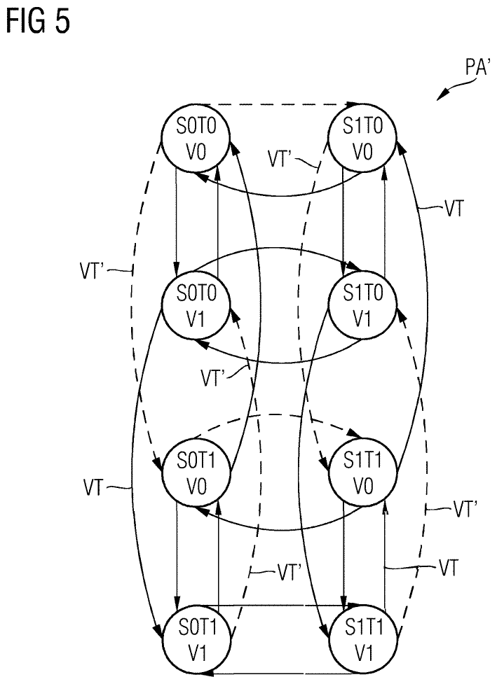

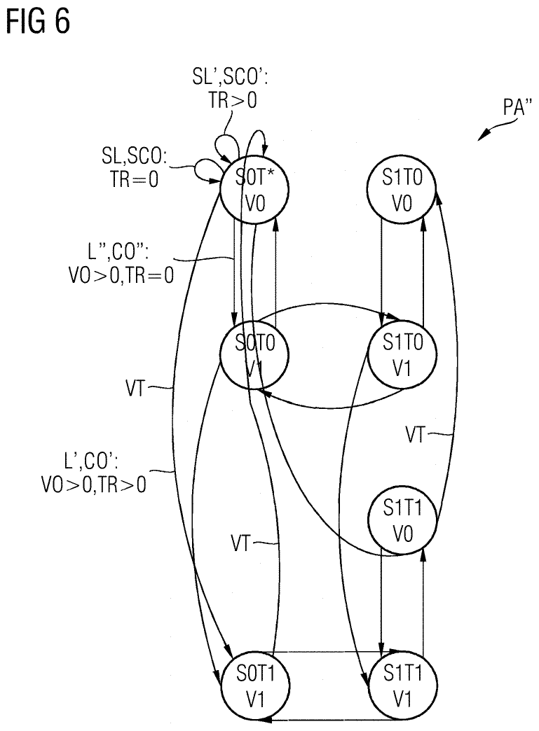

Based on the automatons A1, A2, A3 generated in act S3, a first product automaton is created in act S4 incorporating the labels and trigger conditions as defined for the single automatons A1 to A3. This first product automaton PA is shown in FIG. 4. The product automaton is based on vector states including the respective states of the three variables as well as vector transitions only referring to a state change of a single variable whereas the other variables are unchanged. The vector transitions in FIG. 4 and also in FIGS. 5 and 6 are indicated by arrows VT (only partially designated by this reference numeral) between the vector states, e.g., combinations of states of the variables SP, TR, and VO.

The respective vector transition VT receives the same label and trigger condition as the transition of the single variable within the respective automaton of FIG. 3. This is illustrated in FIG. 4 for vector transitions where the variable SP changes from the state S0 to state S1. In other words, the transition from vector state S0T0V0 to vector state S1T0V0, the transition from vector state S0T0V1 to vector state S1T0V1, the transition from vector state S0T1V0 to vector state S1T1V0, and the transition from vector state S0T1V1 to vector state S1T1V1 receive the label L1 and the trigger condition CO1 (SP>0) as defined for automaton A1 in FIG. 3. In the same way, the other vector transitions in FIG. 4 are defined based on transitions on FIG. 3.

As shown in FIG. 2, the first product automaton PA generated by act S4 is thereafter subjected to a validation act VS1 where the validation act tests whether the first product automaton PA generates outputs corresponding to outputs of the simulation model SM when running a simulation of the motor CO based on the simulation model SM. In case that the validation act VS1 is successful (branch SU from validation act VS1), the method proceeds with act S5 described later on. In case that the validation act VS1 fails (branch FA from validation act VS1), the first product automaton PA may be modified in modification act MO1. This modification is done by a user based on user inputs IN on a user interface UI. After modification act MO1, the validation act VS1 is repeated for the modified product automaton. As mentioned above, a successful validation refers to the result that the outputs of the simulation model and the respective product automaton coincide whereas a failed validation occurs in case that at least one output of the simulation model differs from the corresponding output of the automaton.

After a successful validation act VS1, superfluous vector transitions in the first product automaton PA are removed in act S5 based on predefined rules RU applying to the simulation model SM. Those rules refer to the physical behavior of the motor CO in FIG. 1. The removal of superfluous vector transitions results in a second product automaton PO′ shown in FIG. 4. The removed superfluous vector transitions are indicated by dashed arrows VT′. The removal of the vector transitions VT is based on the following physical laws reflected by the predefined rules RU:

If the voltage is in the state V0, then a transition of the variable TR from T0 to T1 is impossible (no voltage no torque).

If the voltage is in the state V0, then a transition of the variable SP from S0 to S1 is impossible (no voltage no speed).

If the voltage is in the state V1, then a transition of the variable TR from T1 to T0 is impossible (if voltage and torque occurs, then the torque stays).

As shown in FIG. 2, the second product automaton PA′ is subjected to another validation act VS2 in which it is tested whether the second product automaton PA′ generates outputs corresponding to the outputs of the simulation model SM when running a simulation of the motor CO based on the simulation model SM. In case that the validation act VS2 fails (branch FA from act VS2), the second product automaton is modified in modification act MO2 based on user inputs IN on a user interface UI. Thereafter, act S5 is repeated based on the modified second product automaton.

In case that the validation act VS2 succeeds (branch SU from act VS2), the method proceeds with act S6. Act S6 and the subsequent validation and modification acts VS3 and MO3 are optional, and the second product automaton generated in act S5 may be the result, (e.g., the generated state machine), produced by the disclosure. This automaton shows the same behavior as the simulation model SM for the motor CO and may be used in various applications and particularly in control theory.

In act S6 of FIG. 2, several states of the second automaton PO′ are merged. This merging may be done automatically, e.g., states with common regions of variables or region intersections may be combined to one single state. Alternatively, or optionally, the merging may be performed semi-automatically where user inputs IN on a user interface UI specify the states which are to be merged. The merging of states has consequences with respect to the transitions originating or ending at a common vector state representing several merged states, resulting in an adaptation of those transitions. This will be described with respect to FIG. 6 showing a third automaton PA″ resulting from the second automaton PA′ of FIG. 5 by merging two states. In the scenario of FIG. 6, the vector states S0T0V0 and S0T1V0 shown in FIG. 5 are combined to the common vector state S0T*V0 because the torque is not of any interest in case of no speed and no voltage.

As a consequence, the transitions from merged state S0T0V0 to merged state S0T1V0 as well as from merged state S0T1V0 to merged state S0T0V0 need to be represented by new transitions in the form of self-loop transitions. Those self-loop transitions are indicated in FIG. 6 by two arrows starting from the common vector state SOT*V0 and also ending in this common vector state. Each of those self-loop transitions receives a different label and the trigger condition relevant for the original transition between the merged states. In other words, one self-loop transition has the label SL and the trigger condition SCO defined by TR=0 (reflecting the transition from the merged state S0T1V0 to the merged state S0T0V0) whereas the other self-loop transition has the label SL′ and the trigger condition SCO′ defined by TR>0 (reflecting the transition from the merged state S0T0V0 to the merged state S0T1V0).

Due to the generation of the common vector state S0T*V0, there are now two vector transitions originating from this common state to different non-merged states, namely to S0T0V1 and to S0T1V1. To make this non-deterministic behavior deterministic, different labels and trigger conditions are used for those transitions. In other words, the transition from the common vector state S0T*V0 to vector state S0T1V1 receives the label L′ and the trigger condition CO′ defined by VO>0 and TR>0. This corresponds to the vector transition of the state S0T1V0 to S0T1V1 of FIG. 5. Furthermore, the transition from the common vector state S0T*V0 to the non-merged vector state S0T0V1 is represented by a different label L″ and the trigger condition CO″ defined by VO>0 and TR=0. This corresponds to the vector transition from state S0T0V0 to the state S0T0V1 in FIG. 5.

After having conducted the merging as shown in FIG. 6, the third product automaton PA″ resulting therefrom is once again subjected to a validation act VS3 shown in FIG. 2. In this validation act, it is tested whether the third product automaton PA″ generates outputs corresponding to the outputs of the simulation model SM when running a simulation of the motor CO based on the simulation model SM. In case that this validation is successful (branch SU from act VS3), the method terminates with the successfully validated third product automaton. In case that the validation act VS3 fails (branch FA from act VS3), the third product automaton is modified in modification act MO3 based on user inputs IN on a user interface UI. After modification act MO3, the merging according to act S6 is repeated based on the modified third product automaton.

The disclosure as described in the foregoing has several advantageous. Particularly, an automaton is generated which relates automaton states to the state space of a block-based simulation model, making it possible to verify the state changes between simulation and automatons and interpret simulation changes as state changes of the automaton. The transitions in the automaton refer to physically possible state changes of the variables of the corresponding technical component. Trigger conditions for transitions have a physical interpretation in the state space. The ports and interfaces of the block-based simulation model may be mapped to transitions and labels of the automaton, allowing composition of automatons consistent with composition of simulation models. Due to the coupling of a simulation model with an automaton, automaton theories may be used for validation. Furthermore, automatons help to interpret simulation traces in terms of state changes of relevant system states without understanding the underlying simulation model. The automatons generated by the disclosure may be used for an automatic analysis of erroneous behavior and error recovery in simulated technical components, like machines and plants.

It is to be understood that the elements and features recited in the appended claims may be combined in different ways to produce new claims that likewise fall within the scope of the present disclosure. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

While the present disclosure has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1.-14. (canceled)

15. A method for computer-implemented generation of a state machine from a simulated technical component in a block-based simulation model, wherein the state machine comprising a technical component, where the simulated technical component is a block in the simulation model and comprises a plurality of variables, each variable having a value range with variable values configured to be assigned to the respective variable when running a simulation of the technical component based on the simulation model, the method comprising:
selecting one or more variables from the plurality of variables;
generating, for each selected variable, a plurality of discrete states, wherein each state comprises a subset of values from the value range of the respective selected variable;
generating an automaton for each selected variable, wherein a respective automaton is represented by the discrete states of the respective selected variable, and generating one or more transitions from one discrete state to another discrete state of the respective selected variable, wherein a respective transition is referenced by a label and is associated with a trigger condition defining a change of the respective selected variable resulting in the respective transition;
generating a first product automaton from the automatons of all selected variables, wherein the first product automaton comprises a plurality of vector states representing all combinations of discrete states of the selected variables and a plurality of vector transitions for all transitions of single variables, each vector transition corresponding to a transition from one discrete state to another discrete state of a single variable in a respective vector state, where the discrete states of the other variables in the respective vector state remain unchanged, wherein the label and the trigger condition of the respective vector transition correspond to the label and the trigger condition of the transition to which the respective vector transition corresponds; and
removing superfluous vector transitions from the first product automaton based on predefined rules applying to the simulation model, the first product automaton not containing the removed superfluous vector transitions is a second product automaton which is the generated state machine,
wherein the product automaton is reduced in size such that less computational recourses are needed when processing the product automaton compared to the simulation model.

16. The method of claim 15, wherein the selecting is performed at least partly automatically based on a predefined selection of at least one variable, and/or
wherein the selecting is performed at least partly semi-automatically in response to one or more user inputs via a user interface, the one or more user inputs specifying at least one variable to be selected.

17. The method of claim 15, wherein the generating of the plurality of discrete states is performed at least partly automatically based on predefined subsets of values from the value range of one or more selected variables, and/or
wherein the generating of the plurality of discrete states is performed at least partly semi-automatically in response to user inputs via a user interface defining subsets of values from the value range of one or more selected variables.

18. The method of claim 15, wherein the generating of the automation is performed at least partly automatically for at least one selected variable in order to generate an automaton for the at least one selected variable, and/or
wherein the generating of the automation is performed at least partly semi-automatically in response to one or more user inputs via a user interface for at least one selected variable in order to generate the automaton for the at least one selected variable, the one or more user inputs specifying the transitions of the at least one selected variable.

19. The method of claim 15, further comprising:
automatically performing a validation between the generating of the first product automation and the removing of the superfluous vector transitions,
wherein the validation tests whether the first product automaton generates outputs corresponding to outputs of the simulation model when running a simulation of the technical component based on the simulation model,
wherein the method proceeds with the removing of the superfluous vector transitions in case of a successful validation, and
wherein otherwise the method provides an input option on a user interface enabling one or more user inputs to modify the first product automaton, whereupon the generating of the first product automation is repeated based on the modified first product automaton.

20. The method of claim 19, further comprising:
automatically performing an additional validation after the removing of the superfluous vector transitions,
wherein the additional validation tests whether the second product automaton generates outputs corresponding to outputs of the simulation model when running a simulation of the technical component based on the simulation model,
where the method terminates or proceeds with another act without enabling a manual modification of the second product automaton in case of a successful additional validation, and
wherein otherwise the method provides an input option on a user interface enabling one or more user inputs to modify the second product automaton, whereupon the removing of the superfluous vector transitions is repeated based on the modified second product automaton.

21. The method of claim 15, further comprising:
automatically performing a validation after the removing of the superfluous vector transitions,
wherein the validation tests whether the second product automaton generates outputs corresponding to outputs of the simulation model when running a simulation of the technical component based on the simulation model,
where the method terminates or proceeds with another act without enabling a manual modification of the second product automaton in case of a successful validation, and
wherein otherwise the method provides an input option on a user interface enabling one or more user inputs to modify the second product automaton, whereupon the removing of the superfluous vector transitions is repeated based on the modified second product automaton.

22. The method of claim 15, further comprising:
further processing the second product automaton after the removing of the superfluous vector transitions, the further processing comprising one or more merging operations, wherein, in a respective merging operation, several vector states of the second product automaton differing in a value of a single variable are merged to a common vector state substituting the merged vector states, the vector transitions referring to the merged vector states being configured to vector transitions referring to the common vector state, thus resulting in a third product automaton.

23. The method of claim 22, wherein at least one merging operation is performed automatically based on predefined rules, and/or
wherein at least one merging operation is performed semi-automatically in response to one or more user inputs via a user interface, the one or more user inputs specifying the specifying the vector states to be merged.

24. The method of claim 22, wherein the vector transitions of the merged vector states are configured to vector transitions referring to the common state as follows:
i) in case that a vector transition refers to a vector transition from one merged vector state to another merged vector state, a self-loop transition is generated from the common vector state to the common vector state having a new label and the same trigger condition as the vector transition from the merged vector state to the other merged vector state;
ii) in case that there are several vector transitions from a non-merged vector state to different merged vector states, a single vector transition having a new label is generated, the trigger condition being an OR concatenation of the trigger conditions of the several vector transitions; and
iii) in case that there are several vector transitions from different merged vector states to different non-merged vector states being referenced by the same label and trigger condition, each vector transition of the several vector transitions receives a different label and a trigger condition discriminating between different merged vector states.

25. The method of claim 22, further comprising:
automatically performing a validation after the further processing of the second product automation,
wherein the validation tests whether the third product automaton generates outputs corresponding to outputs of the simulation model when running a simulation of the technical component based on the simulation model,
wherein the method terminates in case of a successful validation, and
wherein otherwise the method provides an input option on a user interface enabling one or more user inputs to modify the third product automaton, whereupon the further processing of the second product automation is repeated based on the modified second product automaton.

26. An apparatus for computer-implemented generation of a state machine from a simulated technical component in a block-based simulation model, wherein the state machine comprises a technical component, wherein the simulated technical component is a block in the simulation model and comprises a plurality of variables, each variable having a value range with variable values configured to be assigned to the respective variable when running a simulation of the technical component based on the simulation model, where the apparatus is configured to:
select one or more variables from the plurality of variables;
generate, for each selected variable, a plurality of discrete states, wherein each state comprises a subset of values from the value range of the respective selected variable;
generate an automaton for each selected variable, wherein a respective automaton is represented by the discrete states of the respective selected variable, and generate one or more transitions from one discrete state to another discrete state of the respective selected variable, wherein a respective transition is referenced by a label and is associated with a trigger condition defining a change of the respective selected variable resulting in the respective transition;
generate a first product automaton from the automatons of all selected variables, wherein the first product automaton comprises a plurality of vector states representing all combinations of discrete states of the selected variables and a plurality of vector transitions for all transitions of single variables, each vector transition corresponding to a transition from one discrete state to another discrete state of a single variable in a respective vector state, where the discrete states of the other variables in the respective vector state remain unchanged, wherein the label and the trigger condition of the respective vector transition correspond to the label and the trigger condition of the transition to which the respective vector transition corresponds; and
remove superfluous vector transitions from the first product automaton based on predefined rules applying to the simulation model, the first product automaton not containing the removed superfluous vector transitions is a second product automaton which is the generated state machine,
wherein the product automaton is reduced in size such that less computational recourses are needed when processing the product automaton compared to the simulation model.

27. The apparatus of claim 26, wherein the selection of the one or more variables is performed at least partly automatically by the apparatus based on a predefined selection of at least one variable, and/or
wherein the selection of the one or more variables is performed at least partly semi-automatically by the apparatus in response to one or more user inputs via a user interface, the one or more user inputs specifying at least one variable to be selected.

28. The apparatus of claim 26, wherein the generation of the plurality of discrete states is performed at least partly automatically by the apparatus based on predefined subsets of values from the value range of one or more selected variables, and/or
wherein the generation of the plurality of discrete states is performed at least partly semi-automatically by the apparatus in response to user inputs via a user interface defining subsets of values from the value range of one or more selected variables.

29. The apparatus of claim 26, wherein the generation of the automation is performed at least partly automatically for at least one selected variable by the apparatus in order to generate an automaton for the at least one selected variable, and/or
wherein the generation of the automation is performed at least partly semi-automatically by the apparatus in response to one or more user inputs via a user interface for at least one selected variable in order to generate the automaton for the at least one selected variable, the one or more user inputs specifying the transitions of the at least one selected variable.

30. A computer program product with program code, which is stored on a non-transitory machine-readable carrier, wherein the program code, when executed on a computer, causes the computer to:
select one or more variables from the plurality of variables;
generate, for each selected variable, a plurality of discrete states, wherein each state comprises a subset of values from the value range of the respective selected variable;
generate an automaton for each selected variable, wherein a respective automaton is represented by the discrete states of the respective selected variable, and generate one or more transitions from one discrete state to another discrete state of the respective selected variable, wherein a respective transition is referenced by a label and is associated with a trigger condition defining a change of the respective selected variable resulting in the respective transition;
generate a first product automaton from the automatons of all selected variables, wherein the first product automaton comprises a plurality of vector states representing all combinations of discrete states of the selected variables and a plurality of vector transitions for all transitions of single variables, each vector transition corresponding to a transition from one discrete state to another discrete state of a single variable in a respective vector state, where the discrete states of the other variables in the respective vector state remain unchanged, wherein the label and the trigger condition of the respective vector transition correspond to the label and the trigger condition of the transition to which the respective vector transition corresponds; and
remove superfluous vector transitions from the first product automaton based on predefined rules applying to the simulation model, the first product automaton not containing the removed superfluous vector transitions is a second product automaton which is the generated state machine,
wherein the product automaton is reduced in size such that less computational recourses are needed when processing the product automaton compared to the simulation model.
